(19) United States
(12) Patent Application Publication
(10) Pub. No.: US 2012/0263569 A1
(43) Pub. Date: Oct. 18, 2012

(54) SUBSTRATE HOLDERS AND METHODS OF SUBSTRATE MOUNTING

(76) Inventors: Scott Wayne Priddy, Saint Louis Park, MN (US); Richard Charles Bresnahan, Denmark Township, MN (US)

(21) Appl. No.: 13/446,270

(22) Filed: Apr. 13, 2012

Related U.S. Application Data
(60) Provisional application No. 61/475,392, filed on Apr. 14, 2011.

(51) Int. Cl. C23C 16/458; B65G 65/00

(52) U.S. Cl. 414/800; 118/500

(57) ABSTRACT

A substrate holder for holding a semiconductor substrate for processing in a molecular beam epitaxy system, the substrate including a front side, an opposite backside for epitaxial growth, and an outer edge extending between the front side and the backside, the substrate holder including a body comprising a central opening extending from a backside to a top side of the body, an inner ring surrounding the central opening, and a substrate support lip extending from the inner ring into the central opening, and at least one tensioning device operatively attached to the body and including a cam member and a spring in contact with a portion of the cam member, wherein the spring has a elongated portion and at least two contact portions extending from opposite ends of the elongated portion for contacting the outer edge of the substrate.

### CROSS REFERENCE TO RELATED APPLICATION

This application claims the benefit under 35 U.S.C. §119(e) of U.S. Provisional Patent Application No. 61/475,392, filed Apr. 14, 2011 and titled “Substrate Holders”, which is incorporated herein by reference in its entirety.

### TECHNICAL FIELD

This invention generally relates to an apparatus used in the manufacture of components in the compound semiconductor and related industries. More particularly, the invention relates to a substrate holder for a molecular beam epitaxy (MBE) effusion cell or source or for a metal-organic chemical vapor deposition process (MOCVD).

### BACKGROUND

Molecular beam epitaxy (MBE) is a growth process that involves the deposition of thin films of material onto a substrate in a vacuum by directing molecular or atomic beams onto the substrate. Deposited atoms and molecules migrate to energetically preferred lattice positions on the substrate, which is heated, yielding film growth of high crystalline quality, and optimum thickness uniformity. MBE is widely used in compound semiconductor research and in the semiconductor device fabrication industry, for thin-film deposition of elemental semiconductors, metals, and insulating layers.

A common apparatus utilized in MBE deposition is a thermal effusion cell or source. Thermal effusion cells typically include a crucible that contains the effusion material (e.g., gallium, arsenic, and/or other elements or compounds). The crucible is heated by a resistive filament to heat and effuse the material out of an orifice into an ultra high vacuum growth chamber for deposit on the substrate, which is located in the chamber. Typically, multiple cells are mounted, via ports, in the growth chamber. One or more of the cells are actuated and generate a beam that is directed at a predetermined angle toward the substrate, which is mounted on a substrate holder. Control of the beam is typically accomplished via shutters and/or valves. In use, various preparatory procedures are performed on the substrate, the cells are powered up, heated, and unshuttered. A desired epitaxial deposition is thereby accomplished on the heated, rotating substrate. After growth is completed, the formed wafer is cooled, inspected, and processed for removal from the chamber.

In MBE processes, the position of the substrate within growth chamber is critical to achieving a certain growth of materials on the substrate, which can be accomplished by precisely mounting the substrate to a substrate holder in a variety of different ways. For one example, it is known to secure a substrate within a substrate holder using an adhesive material, such as an adhesive metal that has a relatively low melting point. For another example, a substrate can be mechanically fastened to a substrate holder. In general, currently available substrate holders use many different means in an attempt to support the substrate without over-constraining the wafer in such a way that it is difficult to remove from the substrate holder when desired. It is therefore desirable to provide a substrate holder in which the substrate can be held with as little force as possible while maintaining the substrate in a position in which it can be heated to a uniform temperature while minimizing the risk of deposition material reaching the side of the substrate that is not being treated. It is particularly desirable that such a substrate holder could provide these advantages in a downward facing growth system, such as an MBE system (e.g., the GEN10/20/200/2000 automated MBE systems available from Veeco Instruments Inc.), and/or that the substrate holder could provide these advantages in an upward facing growth system, such as a MOCVD system.

### SUMMARY

In accordance with the invention, substrate holders are provided for use in a MBE system, a metal-organic chemical vapor deposition (MOCVD) system, and/or another system in which it would be advantageous to provide accurate placement and holding of a wafer or substrate. The substrate holders are provided to support substrates or wafers during transfer of the substrate within the processing system. Substrate holders in accordance with the present invention are provided to hold a substrate in known orientation with respect to an alignment feature (e.g., a “flat”) of the substrate and also can provide for self-centering or self-orientation of the substrate. Such a substrate can be used in accordance with a method that shields or masks the backside of the substrate, which is the side that is opposite the side on which deposition takes place. In other words, the substrate holders of the invention are provided to limit deposition to only the front side of the substrate or wafer, which can in part be accomplished by maintaining a substrate in a centered position within a substrate holder during the entire processing operation. In addition, the substrate holder can allow for RHEED characterization during growth. The substrate holder further provides for high temperature resistance, can be resistant to corrosion from growth materials and/or background gasses, and can provide for low out-gassing during use at high temperatures.

In aspects of the substrate holder of the invention, the holder is provided with spring tensioning mechanisms that can hold the substrate while allowing for thermal expansion during the deposition process. In addition, the tensioning mechanism can be configured to prevent rotation of the substrate during transfer of the substrate, during the growth process, and due to vibration of the substrate. In further aspects of the invention, a substrate can be held in a centered position relative to the substrate holder via only one or more tension devices (i.e., without a supporting lip or shelf beneath the substrate).

### BRIEF DESCRIPTION OF THE DRAWINGS

The present invention will be further explained with reference to the appended Figures, wherein like structure is referred to by like numerals throughout the several views, and wherein:

FIG. 1 is a perspective view of a substrate holder of the invention with a substrate positioned therein;

FIG. 2 is a top view of the substrate holder illustrated in FIG. 1;

FIG. 3 is a cross-sectional view of the substrate holder of FIG. 2 taken along section line A-A;

FIG. 4 is a cross-sectional view of the substrate holder of FIG. 1 taken along line C-C of FIG. 3;

FIG. 5 is an enlarged perspective view of a tensioning device positioned relative to a portion of the substrate holder of FIG. 1;

FIG. 6 is a cross-sectional view of a portion of the substrate holder of FIG. 1 taken along section line B-B of FIG. 3;

FIG. 7 is a perspective view of a portion of a substrate holder and tensioning device of the invention, without a substrate holder positioned therein;

FIG. 8 is an exploded perspective view of a portion of a substrate holder and tensioning device of the invention;

FIGS. 9a-9d are a number of different views of an embodiment of a cam member of a tensioning device of the invention;

FIG. 10 is a perspective view of three tensioning devices in an unloaded position relative to a substrate as it can be positioned in a substrate holder of the invention;

FIG. 11 is an enlarged perspective view of the tensioning device in the circled area of FIG. 10;

FIG. 12 is a perspective view of three tensioning devices in a loaded position relative to a substrate as it can be positioned in a substrate holder of the invention;

FIG. 13 is an enlarged perspective view of the tension device in the circled area of FIG. 12;

FIG. 14 is a perspective view of an embodiment of a platen that includes several openings or substrate holder positions;

FIG. 15 is a perspective view of an embodiment of a platen that includes several openings or substrate holder positions, wherein the openings are only accessible from one side of the platen; and

FIG. 16 is an exploded perspective view of a portion of a substrate holder and tensioning device of the invention.

### DETAILED DESCRIPTION

In an aspect of the invention, a substrate holder is provided for a single substrate, wherein the holder includes a holder body that houses one or more tensioning devices generally of the type that are described in detail below. Such exemplary tensioning devices can include a body portion, at least one cam member, and one or more springs for engagement with an edge of a substrate to hold the substrate with a desired amount of tension. The body portion of the tensioning device is placed within a specifically oriented and configured opening of a substrate holder body. Locking or activating the tensioning members can be accomplished by rotating the cam member to lock the spring and cam to a set position that provides a desired amount of tension on the spring.

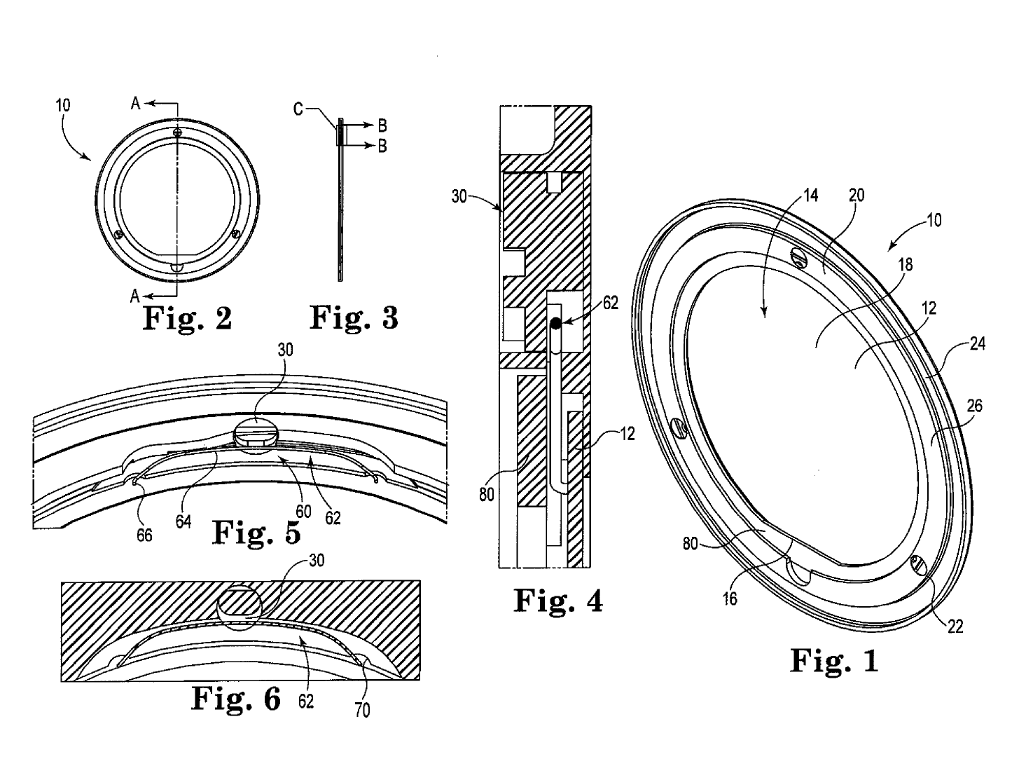

Referring now to the Figures, wherein the components are labeled with like numerals throughout the several Figures, and initially to FIG. 1, an exemplary configuration of a substrate holder 10 of the invention is illustrated with a substrate or wafer 12 positioned in an exemplary location relative to a central opening 14 of the holder. The substrate holder 10 is designed to advantageously provide structures and features for centering the substrate 12 within the holder so that heat transfer to the substrate 12 can be as uniform as possible across its surfaces and so that gaps between the substrate and substrate holder are minimized or prevented. In this way, the amount of useful wafer material that can be provided by a single substrate or wafer can be increased during a controlled substrate processing operation. The substrate holder 10 can also allow for a certain amount of growth or shrinking of the substrate 12 during the processing of the substrate while continuing to accurately maintain the substrate 12 in a desired location.

Substrate holder 10 includes a body 20 having a number of molded or machined features that are described in further detail below. The body 20 further includes at least one opening 22, and in one exemplary embodiment, the body 20 includes three openings 22 spaced from each other around its circumference. More or less than three of such openings 22 can be provided, depending on the desired number of locations of contact with the substrate and the desired positions of these contact locations relative to the outer edges of the substrate. Each of the multiple openings can be spaced at the same distance from an adjacent opening 22, or the openings 22 of a single body 20 can be spaced at different distances from each other.

One embodiment of body 20 of substrate holder 10 includes an optional outer ring 24 and an adjacent main or inner ring 26 in which the openings 22 are positioned. A top surface 32 of a cam member 30 is visible at the top of each of the openings 22, and can be flush with the surface of the inner ring 26, or can be either recessed or extending relative to the surface of the inner ring 26. The top surface 32 of cam member 30 further includes a slot 34 extending across its width, wherein the slot 34 is configured for engagement with some type of a tool, such as a tip of a screwdriver, for example. It is contemplated that the top surface 32 can instead or additionally include other engagement features, such as a slot that only extends across a portion of the width of the top surface, a slot or recess with a different shape other than a straight line, and/or other features that are engageable with a tool for reorientation of the cam member 30. Alternatively, the cam member 30 can be configured so that it can be rotated or otherwise reoriented by hand rather than with a tool.

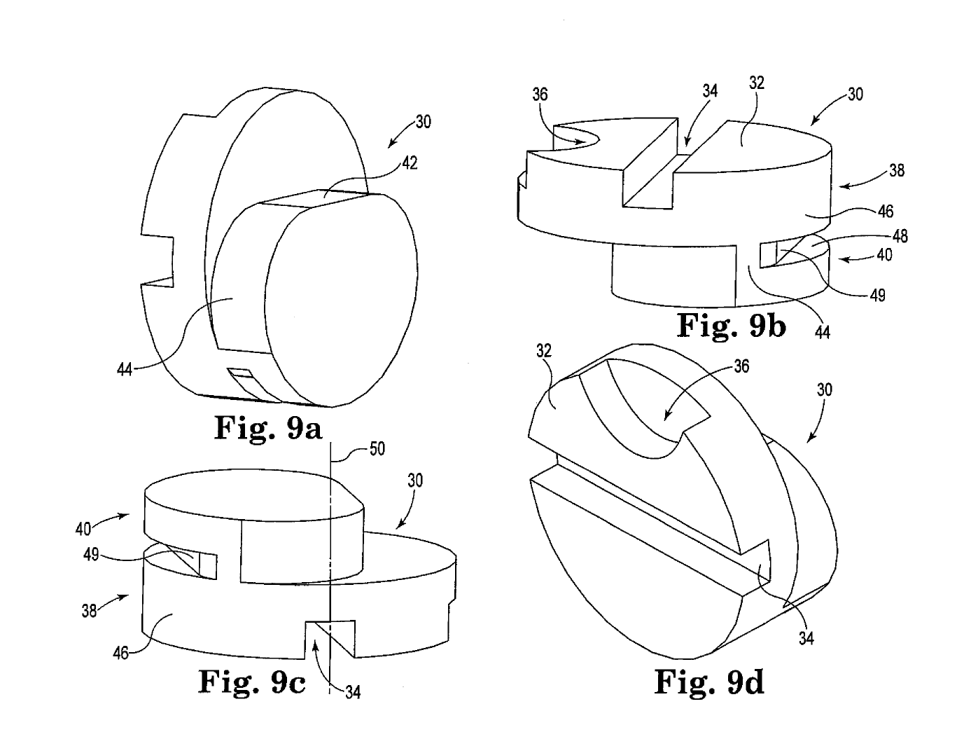

An exemplary embodiment of cam member 30 is shown in several orientations in FIGS. 9a-9d in order to illustrate its various surfaces and features. These figures also illustrate cam member 30 having top surface 32 with the recessed slot 34, as described above. Top surface 32 can further include an indicator 36, which is shown as a notch in this embodiment. The indicator 36 is usable by an operator as a way to visually determine whether the cam member is in a loaded position, an unloaded position, or in between a loaded and unloaded position at any particular time. Thus, the indicator 36 may be a notch as shown, which can be larger, smaller, and/or have a different shape than is illustrated in this embodiment, or may instead be provided as some type of mark or indicia on the top surface 32 that can be easily viewed by the operator. Each cam member 30 can have one or more indicators 36, which may be the same or different from each other. In any case, the cam member 30 can be rotated about its axis until the indicator 36 is in a predetermined position that corresponds to a desired loading condition that is known by the user.

With continued reference to FIGS. 9a-9d, cam member 30 includes a top portion 38 and an adjacent bottom portion 40 extending from the side of top portion 38 that is opposite the top surface 32. The top portion 38 is a generally circular disc that includes top surface 32, slot 34, and one or more indicators 36. The outer diameter of the top portion 38 is at least slightly smaller than the opening 22 of the body 20 in which it will be inserted, and is configured so that it can be rotated relative to the opening 22 in which it is positioned. The bottom portion 40 of cam member 30 can have a wide variety of outer shapes, wherein this exemplary embodiment illustrates the bottom portion 40 as having a flat surface 42 and a curved surface 44 extending from both ends of the flat surface 42 and around the remaining perimeter of the bottom portion 40.

A portion of the curved surface 44 generally follows the curve of an outer surface 46 of the top portion 38 on one side of the top portion 38 so that the flat surface 42 is spaced from the outer curved surface 46 on the opposite side of the top portion 38. Thus, the bottom portion 40 provides eccentricity to the cam member 30 when assembled into a tensioning device, as will be described below. The bottom member 40 further includes a notch or slot 48 that extends generally through the opposite edge of bottom member 40 from the flat surface 42. Notch or slot 48 optionally includes a flat surface 49 that is spaced from the outer curved surface 46 and defines an inner edge of the notch 48. As shown in this embodiment, the flat surface 42 of bottom portion 40 is spaced closer to a central longitudinal axis 50 of the cam member 30 than the flat surface 49 of the notch 48. This different spacing of the flat surfaces 42 and 49 from a longitudinal axis 50 of the cam member 30 is specifically selected and designed to provide a desired amount of tension on a tensioning device.

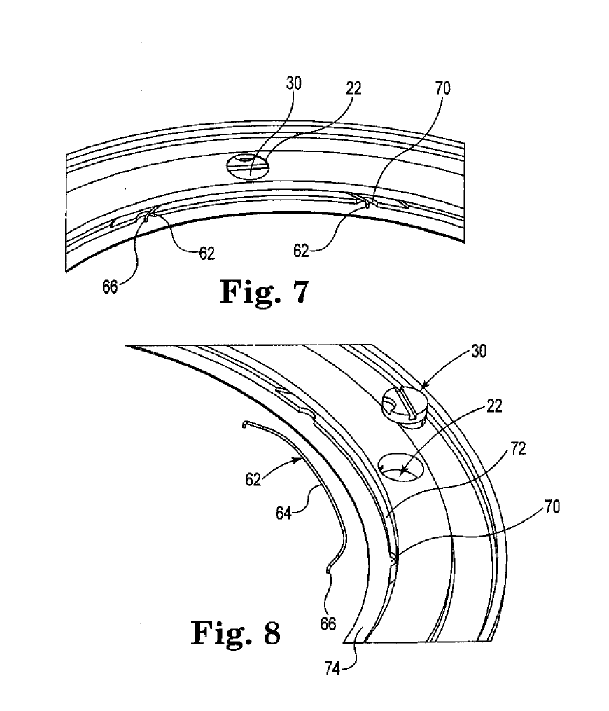

An exemplary configuration of a tensioning device 60 is illustrated in FIGS. 5-8 as it can be oriented relative to body 20 of substrate holder 10. Tensioning device 60 includes cam member 30 and a spring 62. In embodiments of the invention, spring 62 can be made from any material or combination of materials that retains its spring properties at the growth temperature used in the substrate processing. Spring 62 may be made of a variety of materials, including refractory metals such as pure Tungsten wire. Spring 62 may also be made of materials such as alloys of Tungsten/Rhenium/Rhodium/Molybdenum, and/or other materials that meet the temperature requirements of the process, which temperatures can be relatively high. In certain embodiments, the spring can be made from a ceramic material or pyrolytic boron nitride. In cases where the processing temperatures are lower, different materials can be used that do not need the same heat-resistant properties. In any case, it is desirable that the material chosen for the spring performs with desired characteristics when subjected to certain processing temperatures.

As shown, spring member 62 includes an elongated portion 64 and a contact portion 66 extending from each of the ends of elongated portion 64. In the illustrated embodiment, the contact portions 66 extend downwardly at an approximately 90-degree angle from the central axis of the elongated portion 64 and in a downward direction relative to the top surface of the body 20 of holder 10. However, the contact portions 66 can extend at a different angle from the elongated portion 64 and/or the contact portions 66 may be otherwise configured (e.g., curved in one or more directions, or provided with an outer coating material). In any case, the contact portions are configured to provide predetermined points of contact with the edge of a wafer or substrate.

As is illustrated, when the tensioning device 60 is assembled relative to the substrate holder 10, the spring 62 is spaced from the top surface 32 of cam member 30 so that it can contact the cam member 30 in certain locations along its height, depending on whether or not the tensioning device is providing tension to hold a substrate within a substrate holder (i.e., whether the tensioning device is loaded or unloaded). In order to accommodate the various positions of the spring 62 relative to the substrate holder, the inner ring 26 of body 20 includes a relief area or notch 70 along an inner surface of its backing ring support lip 72. Each of the relief areas or notches 70 corresponds with one of the contact portions 66 of spring 62. In this way, the contact portions 66 can be retracted into one of the relief areas 70 when it is desired to release tension on a substrate so that the contact portions 66 do not extend beyond the inner surface of inner ring 26, such as during the process of loading and unloading a substrate or wafer 12.

As can also be seen in these figures that show a substrate holder without a substrate positioned therein (e.g., FIG. 8), body 20 of holder 10 further includes a substrate support lip 74 on which a substrate 12 can rest. The substrate support lip 74 extends at least slightly beyond the backing lip toward the center of the central opening 14 so that it can pass by the backing support lip 72 when a substrate 12 is being inserted into the central opening 14. It is preferable, however, that the amount of overlap between the substrate and the substrate support lip 74 is minimized by designing the width of the support lip 74 to be as small as possible, as is discussed in further detail below.

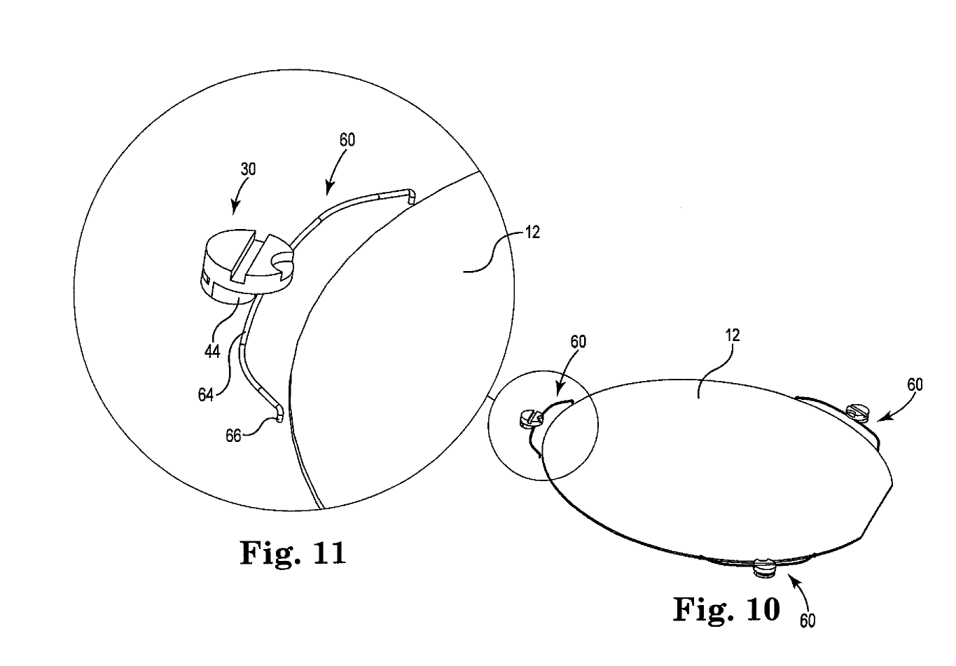

FIGS. 10 and 11 illustrate three tensioning devices 60 as they can be positioned relative to a substrate or wafer 12 before or after the substrate 12 is contacted and held in place via tension from any of the tensioning devices 60. For clarity of illustration and to better view the tensioning devices, the body 20 of holder 10 is not shown in this figure. In this configuration, the cam member 30 is positioned so that the elongated portion 64 of the spring 60 is in contact with the flat surface 42 (not visible in this figure) of bottom portion 40. This position of the tensioning devices 60 can be referred to as an unloaded position, which is the position in which the contact portions 66 of the springs 62 do not contact the outer edge of the substrate 12.

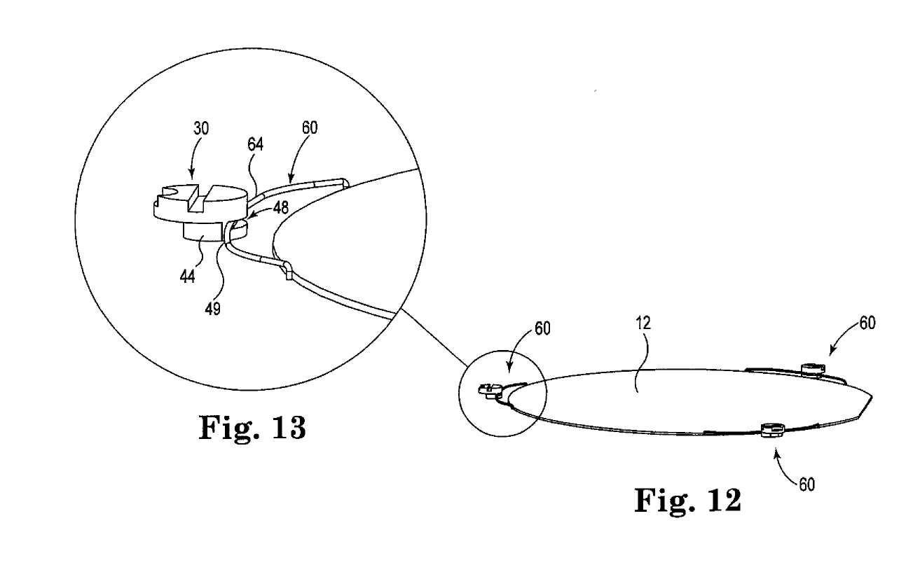

FIGS. 12 and 13 illustrate three tensioning devices 60 as they can be positioned relative to a substrate or wafer 12 when the substrate 12 is being held in place via tension from the tensioning devices 60. In this configuration, the cam member 30 is rotated approximately 180 degrees from its unloaded condition shown in FIGS. 10 and 11 so that the elongated portion 64 of the spring 60 is positioned within the notch 48 of the bottom portion 40, and can be in contact along a portion of its length with the flat surface 49 of the notch 48. This position of the tensioning devices 60 can be referred to as a loaded position, which is the position in which the contact portions 66 of the springs 62 are in contact and pressing against the outer edge of the substrate 12. As is noted above, notch 48 is located so that its furthest point (i.e., the flat surface 49) is further from the centerline 50 of the cam member 30 than the flat surface 42 of bottom portion 40. The difference between these distances from the centerline 50 corresponds to the difference in the distance that the spring 62 can move toward and away from the substrate 12 when rotating the cam member 30 between its loaded position and its unloaded position. Therefore, the amount of travel that is desired for the springs 62 directly corresponds to the amount of tension that can be provided by the spring 62 on a substrate, and the various components of the system are preferably designed and selected to provide a desired amount of tension. For one example, the bottom portion 40 of cam member 30 can be specifically designed and located relative to the top portion 38 to provide a desired amount of movement of the spring 62 toward and away from the substrate. In another example, the spring 62 is provided with a certain predetermined characteristics, such as a particular curvature, flexibility, elastic properties, and/or other features or characteristics that will allow it to react in a predetermined way to movement of the cam member 30.

Referring again to FIG. 1, the substrate holder 10 is shown with a substrate or wafer 12 positioned therein, where the substrate includes a flat portion 16 that can be referred to as an “indicating flat”. Such a flat portion 16 can be used to orient the substrate 12 in a desired orientation, such as an orientation that corresponds to a certain crystal structure or crystal orientation. The substrate 12 can alternatively be provided with more than one flat portion, or the substrate can be provided with one or more different features (e.g., indicia, notches, and the like) that can provide information to the user regarding orientation of the substrate 12. In this exemplary embodiment, when the substrate 12 is positioned within the opening 14 of the substrate holder 10, the flat portion 16 is positioned to correspond with a corresponding flat area of the opening 14. In this illustrated configuration, the surface of the substrate that is visible in the drawing can be referred to as a backside 18 of the substrate 12, and the surface of the body 20 that is visible in the drawing is likewise referred to as the backside of the body 20. In one method of loading the substrate 12, the substrate is positioned with its backside 18 facing upward and inserted into the body 20 from its backside. When the substrate 12 is being treated, such as in an MBE process, the front side of the substrate, which is the surface that is opposite from the backside 18, is at least partially exposed through the central opening 14. This side of the substrate that is opposite the backside 18 can also be referred to as the growth side of the substrate and can therefore be subjected to the MBE processing steps.

In an exemplary embodiment, the size and length of the substrate support lip 74 is minimized in order to maximize the amount of the substrate that is usable after treatment thereof. The ability to center the substrate within the substrate holder and maintain it in this position allows for this lip size to be minimized, since the centered substrate is less likely to allow for gaps to be created between the substrate and the holder. It is further preferable that the substrate support lip 74 is made of a relatively thin material when it is desired to minimize shadowing. After the substrate 12 is positioned in its desired location relative to the body 20, a backing ring 80 can be placed in the central opening 14 so that it contacts the backing ring support lip 72 of the body 20, which spaces it from the substrate 12, as is best illustrated in FIGS. 4 and 8. This backing ring 80 provides shadowing of direct radiation to the edge of the substrate 12. That is, ring 80 can block some of the heat that is generated so that it is acting as a heat or radiation shield to keep the edge of the substrate from getting hotter than desired.

Either before or after the backing ring 80 is inserted into the central opening 14 of the body 20, but after the substrate 12 is located within the opening of the body 20, the tensioning devices 60 can be manipulated to hold the substrate in its desired position. Referring again to FIG. 1, each of the cam members 30 is positioned so that its indicator 36 (shown as a notch in these figures) is facing toward the central opening 14. However, it is not necessary that the indicators 36 are positioned in this orientation, but is only desirable that the operator knows what the position of the indicators are relative to the body 20 for each of the conditions of the tensioning devices. In this embodiment, when an indicator is facing toward the central opening 14, the tensioning device 60 is considered to be unloaded. In this position, the substrate is preferably insertable with minimal to no contact with the springs 62 of the tensioning devices 60. In order to place tension on the substrate 12 with the tensioning devices 60, the cam members 30 can be rotated by a certain predetermined amount (e.g., 180 degrees) to move the contact portions 66 of each of the springs from its respective relief area 70 and into contact with the outer edge of the substrate.

FIG. 14 illustrates an exemplary embodiment of a multiple substrate holder 100. Holder 100 includes many of the same features discussed above relative to substrate holder 10, but holder 100 can accommodate multiple substrates or wafers for processing generally simultaneously. Holder 100 includes three openings 112 that extend at least partially through a platen 110, which is circular in this figure, but could instead have a different shape. Holder 100 may instead include more or less than three openings 112, and it is possible that holder 100 has multiple openings with less than all of the openings containing a substrate during the processing thereof. Each of the openings 112 can be provided with the same or similar features as discussed above relative to the body 20 of substrate holder 10. That is, each of the openings 112 can be provided with an inner ring, multiple tensioning devices (which are generally shown with reference numeral 120, since the only part of the tensioning device visible in this figure is the top surface of a cam body), and an optional backing ring, along with other machined or molded features, such as flat portions and notches.

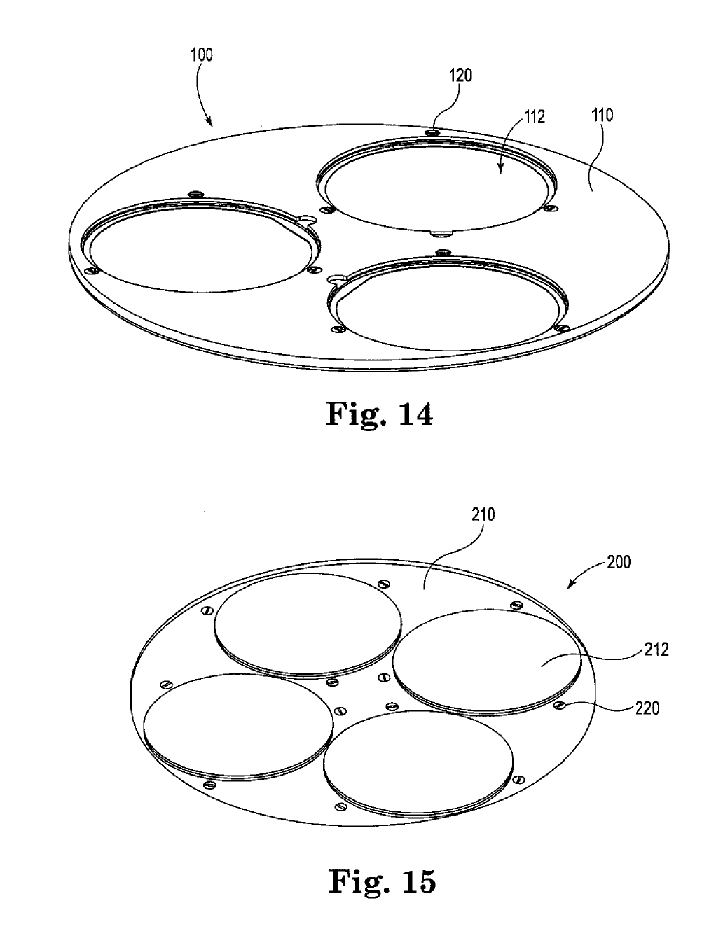

FIG. 15 illustrates another exemplary embodiment of a multiple substrate holder 200, which also includes many of the same features described above relative to substrate holders 10 and 100. In this embodiment, holder 200 includes four openings 212 that extend at least partially through a platen 210; however, the openings 212 may be covered with a material, such as a heat-resistant material, on one side of the platen 210 (shown as the bottom side in this figure). This backing material allows for different processing than the substrate holders of the invention that include a hole extending through the entire substrate holder 10. In particular, a substrate can be oriented so that its backside is loaded into the holder 200 from its backside, and then the backside will be treated, since the opposite or “front” side will be covered with the material that covers the openings 212. In this orientation, all of the substrate or wafer can be coated, thereby maximizing the usable material available from each substrate. A platen that only allows for one exposed side of substrates, such as is provided with the holder 200, can be used in a metal-organic chemical vapor deposition process (MOCVD), for example, in which thin layers of atoms are deposited onto a semiconductor substrate or wafer. Each of the openings 212 can be provided with the same or similar features as discussed above relative to the body 20 of substrate holder 10. That is, each of the openings 212 can be provided with an inner ring, multiple tensioning devices (which are generally shown with reference numeral 220, since the only part of the tensioning device visible in this figure is the top surface of a cam body), and an optional backing ring, along with other machined or molded features, such as flat portions and notches.

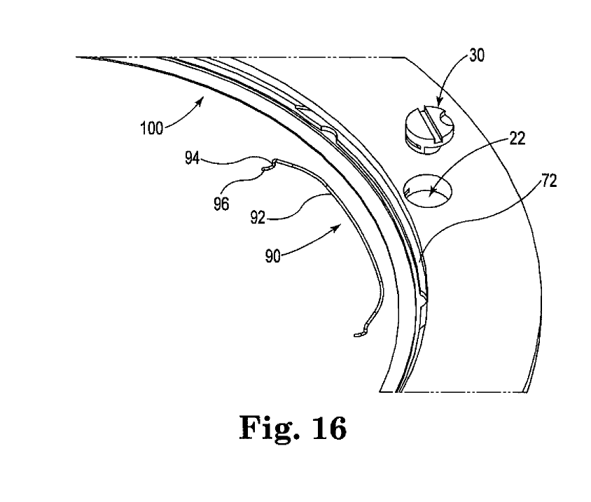

FIG. 16 illustrates a portion of a substrate holder 100 that is similar to substrate holder 10 described above, but this exemplary embodiment does not have a substrate holder lip to support the substrate when it is inserted into the holder 100. Instead, this substrate holder 100 includes a spring 90 that can be used both to support a substrate relative to the height of the holder 100 and also to provide tension to hold the substrate centered relative to a central opening of the holder. In other words, if the substrate holder 100 is positioned on a horizontal surface during loading thereof, the spring 90 can be said to provide both horizontal and vertical support to an inserted substrate. In order to accomplish this, the exemplary embodiment of spring 90 includes an elongated portion 92, a contact portion 94 extending at an angle from the ends of elongated portion 92, and a support portion 96 extending from the distal end of each of the contact portions 94. In this embodiment, each of the contact portions 94 extends at an approximate 90-degree angle from the ends of the elongated portion 92, and each of the support portions 96 extends at an approximate 90-degree angle from a distal end of a contact portion 94. The angles at which the contact portion 94 and support portion 96 extend from their respective adjacent portions can vary widely, but are generally configured so that each contact portion can press against an edge of a substrate to provide tension on the substrate and so that each support portion can provide support to the bottom of the substrate so that it does not fall through the central opening of the substrate holder. It is understood that the contact portions 94 and support portions 96 can extend at different angles than shown and/or the contact portions 94 and support portions 96 may be otherwise configured (e.g., curved in one or more directions, or provided with an outer coating material).

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

1. A substrate holder for holding a semiconductor substrate for processing in a molecular beam epitaxy system, the substrate including a front side for epitaxial growth, an opposite backside, and an outer edge extending between the front side and the backside, the substrate holder comprising:
a body comprising a central opening extending from a backside to a top side of the body, an inner ring surrounding the central opening, and a substrate support lip extending from the inner ring into the central opening;
at least one tensioning device operatively attached to the body and comprising a cam member and a spring in contact with a portion of the cam member, wherein the spring comprises an elongated portion having opposite ends and a contact portion extending from each of the opposite ends of the elongated portion for contacting the outer edge of the substrate.

2. The substrate holder of claim 1, further comprising a backing ring support lip spaced from the substrate support lip and extending from the inner ring into the central opening.

3. The substrate holder of claim 2, further comprising a backing ring adjacent to and at least partially overlapping the backing ring support lip.

4. The substrate holder of claim 2, wherein the backing ring support lip comprises at least two notches, and wherein each of the two contact portions of one of the springs is positioned within one of the notches of the backing ring support lip when the tensioning device is in an unloaded configuration.

5. The substrate holder of claim 4, wherein the backing ring comprises an inner circumferential surface, and wherein neither of the contact portions extends past the inner circumferential surface when the tensioning device is in an unloaded configuration.

6. The substrate holder of claim 1, wherein the cam member comprises:
a first body portion comprising a top surface, a bottom surface, and an outer peripheral surface;
a second body portion extending from the bottom surface of the first body portion and comprising:
a notch extending from its periphery and toward a central longitudinal axis of the cam member; and
an eccentric outer surface.

7. The substrate holder of claim 6, wherein the tensioning device comprises an unloaded configuration in which the elongated portion of the spring is in contact with the eccentric outer surface, and a loaded configuration in which the elongated portion of the spring is positioned within the notch of the second body portion.

8. The substrate holder of claim 7, wherein the body further comprises at least one opening through its backside, and wherein each of the tensioning devices is positioned so that its cam member is located in one of the openings through the backside of the body.

9. The substrate holder of claim 8, wherein each cam member is rotatable relative to its respective opening through the backside of the body.

10. The substrate holder of claim 1, comprising at least three tensioning devices spaced from each other around the inner ring of the body.

11. The substrate holder of claim 1, in combination with a platen that comprises at least a second additional substrate holder that comprises a second central opening, a second inner ring, and a second support lip extending from the second inner ring toward the second central opening, the platen comprising at least one tensioning device operatively attached to the second additional substrate holder and comprising a cam member and a spring.

12. A substrate holder for holding a semiconductor substrate for processing in a molecular beam epitaxy system, the substrate including a front side for epitaxial growth, an opposite backside, and an outer edge extending between the front side and the backside, the substrate holder comprising:
a body comprising a central opening extending from a backside to a top side of the body, and an inner ring surrounding the central opening, and a substrate support lip extending from the inner ring into the central opening;
at least one tensioning device operatively attached to the body and comprising a cam member and a spring in contact with a portion of the cam member, wherein the spring comprises a elongated portion, at least two contact portions, each of which extends from one of the opposite ends of the elongated portion for contacting the outer edge of the substrate, and at least two support portions, each of which extends from a distal end of one of the contact portions for supporting the front side of the substrate.

13. The substrate holder of claim 12, wherein the tensioning device comprises an unloaded configuration in which the elongated portion of the spring is in contact with the eccentric outer surface, and a loaded configuration in which the elongated portion of the spring is positioned within the notch of the second body portion.

14. A method of loading a substrate into a substrate holder that comprises a body comprising a central opening extending from a backside to a top side of the body, an inner ring surrounding the central opening, and a substrate support lip extending from the inner ring into the central opening, and at least one tensioning device operatively attached to the body and comprising a cam member and a spring in contact with a portion of the cam member, wherein the spring comprises a elongated portion and a contact portion extending from each of the opposite ends of the elongated portion for contacting the outer edge of the substrate, the method comprising the steps of:
placing a substrate into the central opening of the body from the backside of the body with the at least one tensioning member in an unloaded condition;
manipulating the at least one tensioning device to move it to its loaded condition in which the contact portions of the spring are in contact with an outer edge of the substrate.

15. The method of claim 14, wherein the step of manipulating the at least one tensioning device comprises rotating the cam member relative to the backside of the body to move the tensioning device from its unloaded condition to its loaded condition.
